(19) United States
(12) Patent Application Publication
(10) Pub. No.: US 2014/0239951 A1
(43) Pub. Date: Aug. 28, 2014

(54) MR ELECTRICAL PROPERTIES TOMOGRAPHY

(71) Applicant: KONINKLIJKE PHILIPS N.V., EINDHOVEN (NL)

(72) Inventors: Astrid Lucia Helena Maria Willemina Van Lier, Apeldoorn (NL); Cornelis Antonius Theodorus Van Den Berg, Ultrecht (NL); Ulrich Katscher, Hamburg (DE)

(73) Assignee: Koninklijle Philips N.V., Eindhoven (NL)

(21) Appl. No.: 14/351,977

(22) PCT Filed: Oct. 16, 2012
(86) PCT No.: PCT/IB2012/055619

§ 371 Date: Apr. 15, 2014

Related U.S. Application Data
(60) Provisional application No. 61/548,445, filed on Oct. 18, 2011.

(51) Int. Cl. G01R 33/48; G01R 33/28

(52) U.S. Cl. CPC G01R 33/48; G01R 33/28
USPC 324/309; 324/318

(57) ABSTRACT

The invention relates to a method of MR imaging of an object (10) placed in an examination volume of a MR device (1). It is an object of the invention to enable improved electrical properties tomography. The invention proposes that the method comprises the steps of:—subjecting the object (10) to two or more imaging sequences for acquiring MR signals, wherein the imaging sequences each comprise at least one RF pulse and at least one switched magnetic field gradient; reconstructing two or more MR phase images from MR signals acquired by means of imaging sequences comprising switched magnetic field gradients of opposed polarity; deriving a spatial distribution of electrical properties of the object (10) from the MR phase images.

### FIELD OF THE INVENTION

The invention relates to the field of magnetic resonance (MR) imaging. It concerns a method of MR imaging of an object placed in an examination volume of a MR device. The invention also relates to a MR device and to a computer program to be run on a MR device.

### BACKGROUND OF THE INVENTION

Image-forming MR methods which utilize the interaction between magnetic fields and nuclear spins in order to form two-dimensional or three-dimensional images are widely used nowadays, notably in the field of medical diagnostics, because for the imaging of soft tissue they are superior to other imaging methods in many respects, do not require ionizing radiation and are usually not invasive.

### SUMMARY OF THE INVENTION

According to the MR method in general, the object (e.g. the body of a patient) to be examined is arranged in a strong, uniform magnetic field whose direction at the same time defines an axis (normally the z-axis) of the co-ordinate system on which the measurement is based. The magnetic field produces different energy levels for the individual nuclear spins in dependence on the magnetic field strength which can be excited (spin resonance) by application of an electromagnetic alternating field (RF field) of defined frequency (so-called Larmor frequency, or MR frequency). From a macroscopic point of view the distribution of the individual nuclear spins produces an overall magnetization which can be deflected out of the state of equilibrium by application of an electromagnetic pulse of appropriate frequency (RF pulse) while the magnetic field extends perpendicular to the z-axis, so that the magnetization performs a precessional motion about the z-axis. The precessional motion describes a surface of a cone whose angle of aperture is referred to as flip angle. The magnitude of the flip angle is dependent on the strength and the duration of the applied electromagnetic pulse. In the case of a so-called 90° pulse, the spins are deflected from the z axis to the transverse plane (flip angle 90°).

After termination of the RF pulse, the magnetization relaxes back to the original state of equilibrium, in which the magnetization in the z direction is built up again with a first time constant T₁ (spin lattice or longitudinal relaxation time), and the magnetization in the direction perpendicular to the z direction relaxes with a second time constant T₂ (spin-spin or transverse relaxation time). The variation of the magnetization can be detected by means of receiving RF coils which are arranged and oriented within an examination volume of the MR device in such a manner that the variation of the magnetization is measured in the direction perpendicular to the z-axis. The decay of the transverse magnetization is accompanied, after application of, for example, a 90° pulse, by a transition of the nuclear spins (induced by local magnetic field inhomogeneities) from an ordered state with the same phase to a state in which all phase angles are uniformly distributed (dephasing). The dephasing can be compensated by means of a refocusing pulse (for example a 180° pulse). This produces an echo signal (spin echo) in the receiving coils.

In order to realize spatial resolution in the object, linear magnetic field gradients extending along the three main axes are superposed on the uniform magnetic field, leading to a linear spatial dependency of the spin resonance frequency. The signal picked up in the receiving coils then contains components of different frequencies which can be associated with different locations in the object. The signal data obtained via the receiving coils corresponds to the frequency domain and is called k-space data. The k-space data usually includes multiple lines acquired with different phase encoding. Each line is digitized by collecting a number of samples. A set of k-space data is converted to a MR image by means of Fourier transformation or other suitable reconstruction algorithms.

The determination of the spatial distribution of electrical properties of biological tissues is of major interest because the complex permittivity of biological tissues is affected by their composition. As the cellular composition of tumors differs from healthy tissue, it was for example found that the conductivity of glioma is different than the conductivity of the surrounding healthy tissue (see Lu et al., Int. J. Hyperthermia, 8:755-60, 1992).

Recently, MR imaging-based methods have been developed that enable the examination of the (complex) permittivity or (only) the conductivity of biological tissues. In so-called MR current density imaging (MR CDI), an external current source is connected to the skin of a patient to be examined in order to inject electrical current into the tissue. The current in the tissue locally alters the main magnetic field strength. This effect is used to image the current density distribution within the tissue by means of acquiring MR phase images (Scott et al., IEEE Trans. Med. Imag., 10:362-74, 1991). Using appropriate post-processing steps, the spatial distribution of the electrical conductivity can be derived from the obtained current density map. This approach is referred as MR electrical impedance mapping (MR EIT, see Seo et al., IEEE Trans. Biomed. Eng., 50:1121-1124, 2003). These MR CDI and MR EIT techniques are generally performed by applying a DC current for a few milliseconds. Hence, the obtained conductivity is associated with the “low” frequency range (below ˜1 kHz).

A drawback of both of the afore-described MR CDI and MR EIT techniques is that they require an external current source which is not available in a standard MR imaging environment. The current source has to be connected to the skin surface of the examined patient in order to inject a current. A major issue is that a comparatively high current is required to obtain a sufficient signal-to-noise ratio. Such high currents may be painful for the examined patient.

Moreover, a method has recently been developed, which enables the determination of the spatial distribution of electrical properties and for which no external current source is needed anymore. This method, which is referred to MR EPT (MR electrical properties tomography, see WO 2007/017 779 A2), is based on the insight that the radio frequency field needed for excitation of nuclear spins in MR imaging is altered by the complex permittivity of the tissue. By determining the excitation field, the electrical conductivity can directly be reconstructed. However, the frequency range of the determined complex electrical permittivity is restricted to the MR frequency of the used MR apparatus. The MR frequency typically ranges from 64 to 300 MHz. This frequency range is far off the β-dispersion band (about 1 MHz), which is of particular interest due to its relation to cell-membrane information (see Martinsen et al., Encyclopedia of Surface and Colloid Science, 2643-52, 2002). Moreover, only a single frequency examination can be performed with a given MR apparatus.

From the foregoing it is readily appreciated that there is a need for an improved MR EPT technique.

In accordance with the invention, a method of MR imaging of an object placed in an examination volume of a MR device is disclosed. The method comprises the steps of:

subjecting the object to two or more imaging sequences for acquiring MR signals, wherein the imaging sequences each comprise at least one RF pulse and at least one switched magnetic field gradient;

reconstructing two or more MR phase images from MR signals acquired by means of imaging sequences comprising switched magnetic field gradients of opposed polarity;

deriving a spatial distribution of electrical properties of the object from the MR phase images.

The gist of the invention, which can be referred to as “gradient-EPT”, is that the electromagnetic fields induced by the switched magnetic field gradients applied for spatial encoding in MR imaging are used. In this way, the invention combines the advantages of both MR EIT/MR CDI (determination of electrical properties in the frequency range of particular biological interest) and “RF-EPT” (determination of electrical properties without current injection). Furthermore, the use of the switched magnetic field gradients directly enables the determination of the complex permittivity at different frequencies. Hence, a spectrum of the electrical properties can be determined.

The invention is based on the insight that the switching of the magnetic field gradients in MR imaging results in a time-varying magnetic field, which generates (through induction) eddy currents within the examined object. The eddy current distribution depends on the electrical conductivity of the tissue. Since the eddy currents locally disturb the main magnetic field, the spatial distribution of electrical properties of the object can be derived directly from the acquired MR signals.

According to the invention, phase differences in the acquired MR signals, which are due to the induced eddy currents, are measured at opposed polarities of the switched magnetic field gradients. In this way, the spatial distribution of the current density of the eddy currents can directly be derived. Once the current density distribution is reconstructed, the underlying electrical conductivity can be deduced.

An essential feature of the invention is thus that two (or more) MR images reconstructed from the acquired MR signals differ only with respect to their eddy-current induced phase. For example, subtracting these two MR images yields an MR image containing only the eddy-current induced phase, which can be used for deriving a spatial distribution of electrical properties of the object in accordance with the invention.

In a preferred embodiment of the invention, the MR signals are acquired during a transient phase of magnetic field gradient switching. A “transient phase” means that the MR signals are acquired during a time interval during which the magnetic field is not temporarily constant. For example, the MR signals can be acquired during a ramp-up and/or a ramp-down phase of magnetic field gradient switching according to the invention.

The frequency of the eddy currents induced due to magnetic field gradient switching depends on the ramping process, i.e. the temporal profile (waveform) of the switched magnetic field gradients. By varying the magnetic field gradient waveform, a range of frequencies that are significantly lower than the MR frequency can be probed and a corresponding spectral distribution of electrical properties of the examined object can be derived from the acquired MR signals.

The method of the invention described thus far can be carried out by means of a MR device including at least one main magnet coil for generating a uniform steady magnetic field within an examination volume, a number of gradient coils for generating switched magnetic field gradients in different spatial directions within the examination volume, at least one RF coil for generating RF pulses within the examination volume and/or for receiving MR signals from an object positioned in the examination volume, a control unit for controlling the temporal succession of RF pulses and switched magnetic field gradients, and a reconstruction unit. The method of the invention can be implemented, for example, by a corresponding programming of the reconstruction unit and/or the control unit of the MR device.

The method of the invention can be advantageously carried out in most MR devices in clinical use at present. To this end it is merely necessary to utilize a computer program by which the MR device is controlled such that it performs the above-explained method steps of the invention. The computer program may be present either on a data carrier or be present in a data network so as to be downloaded for installation in the control unit of the MR device.

### BRIEF DESCRIPTION OF THE DRAWINGS

The enclosed drawings disclose preferred embodiments of the present invention. It should be understood, however, that the drawings are designed for the purpose of illustration only and not as a definition of the limits of the invention. In the drawings:

FIG. 1 shows a MR device for carrying out the method of the invention;

FIG. 2 shows a diagram illustrating the method of the invention.

### DETAILED DESCRIPTION OF EMBODIMENTS

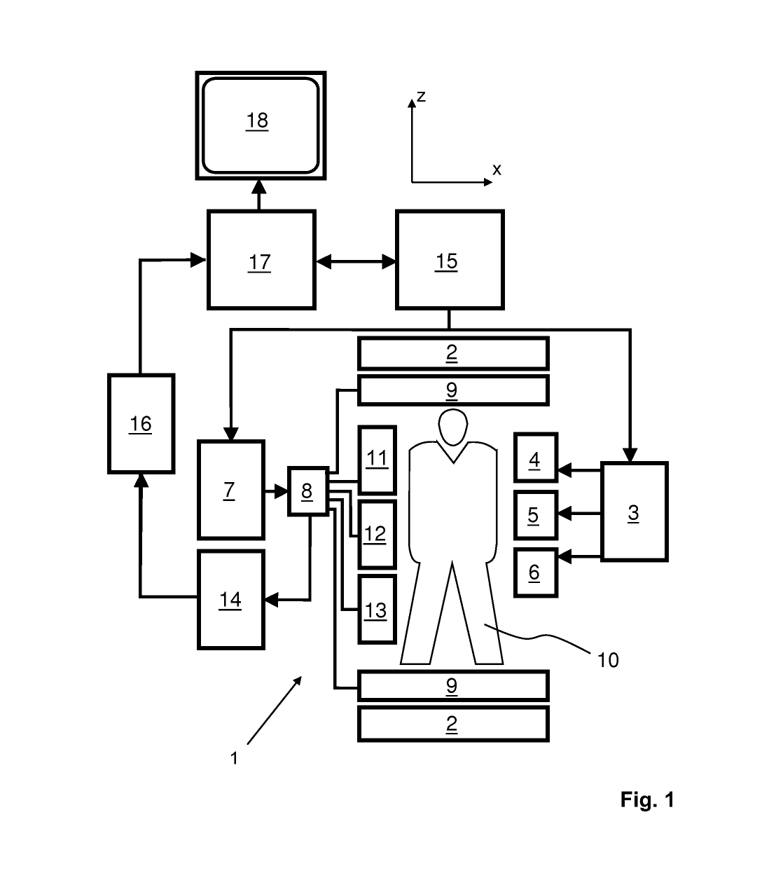

With reference to FIG. 1, a MR device 1 is shown. The device comprises superconducting or resistive main magnet coils 2 such that a substantially uniform, temporally constant main magnetic field is created along a z-axis through an examination volume.

A magnetic resonance generation and manipulation system applies a series of RF pulses and switched magnetic field gradients to invert or excite nuclear magnetic spins, induce magnetic resonance, refocus magnetic resonance, manipulate magnetic resonance, spatially and otherwise encode the magnetic resonance, saturate spins, and the like to perform MR imaging.

Most specifically, a gradient pulse amplifier 3 applies current pulses to selected ones of whole-body gradient coils 4, 5 and 6 along x, y and z-axes of the examination volume. A digital RF frequency transmitter 7 transmits RF pulses or pulse packets, via a send-/receive switch 8, to a whole-body volume RF coil 9 to transmit RF pulses into the examination volume. A typical MR imaging sequence is composed of a packet of RF pulse segments of short duration which taken together with each other and any applied magnetic field gradients achieve a selected manipulation of nuclear magnetic resonance. The RF pulses are used to saturate, excite resonance, invert magnetization, refocus resonance, or manipulate resonance and select a portion of a body 10 positioned in the examination volume. The MR signals are also picked up by the whole-body volume RF coil 9.

For generation of MR images of limited regions of the body 10 by means of parallel imaging, a set of local array RF coils 11, 12, 13 are placed contiguous to the region selected for imaging. The array coils 11, 12, 13 can be used to receive MR signals induced by body-coil RF transmissions.

The resultant MR signals are picked up by the whole body volume RF coil 9 and/or by the array RF coils 11, 12, 13 and demodulated by a receiver 14 preferably including a preamplifier (not shown). The receiver 14 is connected to the RF coils 9, 11, 12 and 13 via send-/receive switch 8.

A host computer 15 controls the gradient pulse amplifier 3 and the transmitter 7 to generate any of a plurality of MR imaging sequences, such as echo planar imaging (EPI), echo volume imaging, gradient and spin echo imaging, fast spin echo imaging, and the like. For the selected sequence, the receiver 14 receives a single or a plurality of MR data lines in rapid succession following each RF excitation pulse. A data acquisition system 16 performs analog-to-digital conversion of the received signals and converts each MR data line to a digital format suitable for further processing. In modern MR devices the data acquisition system 16 is a separate computer which is specialized in acquisition of raw image data.

Ultimately, the digital raw image data is reconstructed into an image representation by a reconstruction processor 17 which applies a Fourier transform or other appropriate reconstruction algorithms. The MR image may represent a planar slice through the patient, an array of parallel planar slices, a three-dimensional volume, or the like. The image is then stored in an image memory where it may be accessed for converting slices, projections, or other portions of the image representation into appropriate format for visualization, for example via a video monitor 18 which provides a man-readable display of the resultant MR image.

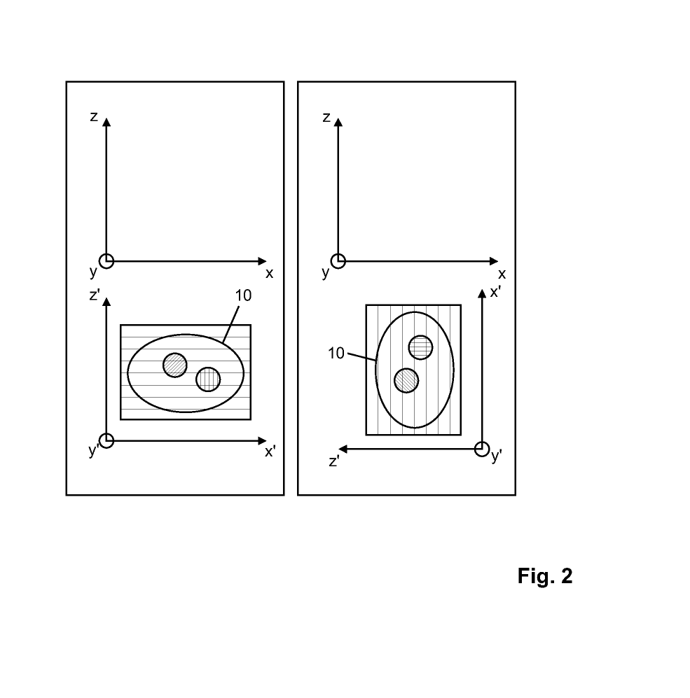

With continuing reference to FIG. 1 and with further reference to FIG. 2 an embodiment of the imaging approach of the invention is explained.

In accordance with the invention, the applied imaging sequence comprises RF pulses and switched magnetic field gradients, wherein the MR signals are preferably acquired during a transient phase of magnetic field gradient switching. The spatial distribution of electrical properties of the body is derived from the MR signals acquired in this way.

The derivation of electrical properties is based on Ampere's law as follows:

\vec{J}(r)=σ(r)\vec{E}(r)=∇×\vec{B}(r)/μ

The z-component of this equation can be written as:

J_{z} (r)=σ(r)E_{z} (r)=(∂ₓB_{y} (r)−∂_{y}Bₓ(r))/μ

Herein, J is the current density, σ is the electrical conductivity, E is the electric field and B is the magnetic field. The magnetic field, which is induced by the eddy currents generated during magnetic field gradient switching, can be derived in accordance with the invention from the MR image phase. Two or more MR phase images are reconstructed from MR signals acquired by means of imaging sequences respectively comprising switched magnetic field gradients of opposed polarity. In the following, the image phase in the MR phase images reconstructed from MR signals acquired by means of the “original” magnetic field gradient polarization is designated as φ_{org} and the image phase in the MR phase images reconstructed from MR signals acquired by using switched magnetic field gradients of opposed polarity is designated as φᵢₙᵥ. The eddy current induced magnetic field can then be computed as:

B_{z}(r)=(φ_{org}(r)−φᵢₙᵥ(r))/(2τγ)

Herein, γ is the gyromagnetic ratio and τ is the effective duration of the eddy current. The knowledge of τ is required only in the case that absolute values of J are to be derived. Without additional measurements, the sum of the phases can be used to determine the conductivity at Larmor frequency via, e.g.,

σ_{Larmor} (r)˜Δ(φ_{org}(r)+φᵢₙᵥ(r))

The complex permittivity can be determined accordingly.

According to the invention, the body of the patient 10 is subjected to a first imaging sequence for acquiring first MR signals, wherein the first imaging sequence comprises switched magnetic field gradients having the original gradient polarization. The MR signals may be acquired during a transient phase (e.g. during a ramp-up and/or a ramp-down phase) of magnetic field gradient switching. In a next step, the body 10 of the patient is subjected to a second imaging sequence for acquiring second MR signals, wherein the switched magnetic field gradients of the second imaging sequence have inverted polarity. No extra gradients have to be added to the imaging sequence. The described pair of MR signal data can be obtained, for example, by inverting the original selection, preparation, or readout gradient, or any combination of these three gradients. A MR image resulting from the second MR signals appears mirrored along the inverted gradient direction and has to be mirrored back to the original orientation before further image reconstruction. 3-dimensional MR phase images φ_{org}(r) and φᵢₙᵥ(r) are reconstructed from the first and second MR signals. On this basis, the eddy current induced magnetic field is computed by means of the above formula. In order to obtain the current density distribution, further signal acquisition steps are required. After acquisition of the first and second MR signals, the examined body 10 (or at least the part of the body 10 which is actually examined) is rotated about an axis perpendicular to the main magnetic field axis of the MR device, preferably by 90°. Thereafter, the body 10 of the patient is subjected to a third imaging sequence for acquiring third MR signals, wherein the third imaging sequence comprises switched magnetic field gradients having again the original polarity. Finally, the body 10 of the patient is subjected to a forth imaging sequence for acquiring forth MR signals, wherein the forth imaging sequence comprises switched magnetic field gradients having the inverted polarity. On the basis of the first, second, third and forth MR signals, the above equation for computing the current density can be solved.

The acquisition of the first and second MR signals is illustrated in FIG. 2 in the left part of the diagram. The acquisition of the third and forth MR signals is illustrated in the right part. The acquisition of the first and second MR signals comprises the scanning of several transverse slices through the body 10, wherein the feet-head direction of the body 10 corresponds to the “longitudinal” z-axis of the MR device 1. The phase differences φ_{org}(r)-φᵢₙᵥ(r) between the first and second MR signals are proportional to the feet-head directed magnetic field induced by the eddy currents (corresponding to B_{z′} in the coordinate frame of the body 10). Then the sample is rotated by 90° about the anterior-posterior axis y of the MR device 1, and the acquisition of the third and forth MR signals is performed in sagittal slice orientation. The same magnitude MR images are obtained as before. However, now the feet-head direction of the MR device 1 corresponds to the x′-direction in the coordinate frame of the body 10 of the patient. Hence, the z-component of the curl of the magnetic field and thus current density in this direction can be calculated by using the above formulas.

Instead of two measurements with orthogonal orientation of the patient's body 10, also two (or more) signal acquisition steps with linearly independent magnetic field gradient directions are possible. In this way, the need for the (sometimes impractical) rotation of the patient's body 10 can be eliminated. For instance, multiple pairs of slices with original and inverted gradients can be acquired with sequentially stepping the slice orientation by a certain rotation angle. The subsequent image reconstruction can contain averaging the resulting images, or using a back-projection method. Alternatively, sometimes sufficient image contrast can be achieved by acquiring only one image pair for a single slice orientation and a single patient orientation. Once the current density distribution is reconstructed in the above-described manner, the underlying electrical conductivity can be deduced with methods described in the literature (see Seo et al., IEEE Trans. Biomed. Eng., 50:1121-1124, 2003).

1. Method of MR imaging of an object placed in an examination volume of a MR device, the method comprising the steps of:
subjecting the object to two or more imaging sequences for acquiring MR signals, wherein the imaging sequences each comprise at least one RF pulse and at least one switched magnetic field gradient for spatial encoding in the MR imaging;
reconstructing two or more MR phase images from MR signals acquired by means of said two imaging sequences in which the switched magnetic field gradients of one of the imaging sequences for spatial encoding in the MR imaging has opposed polarity relative to the switched magnetic field gradients of one of the imaging sequences;
deriving a spatial distribution of electrical properties of the object from the image phases of the MR phase images.

2. Method of claim 1, wherein spatial distribution of electrical properties of the object (10) is derived from the MR phase mines on the basis of Ampère's law relating the current density^{,} to the spatial derivatives of the gradient magnetic field components.

3. (canceled)

4. Method of claim 1, wherein the imaging sequence comprises switched magnetic field gradients having a varying temporal profile, and wherein a spectral distribution of electrical properties of the object is derived from the acquired MR signals.

5. Method of claim 1, comprising the steps of:
subjecting the object to a first imaging sequence for acquiring first MR signals;
subjecting the object to a second imaging sequence for acquiring second MR signals, wherein the switched magnetic field gradients of the first and second imaging sequence have opposed polarity;
subjecting the object to a third imaging sequence for acquiring third MR signals;
subjecting the object to a forth imaging sequence for acquiring fourth MR signals, wherein the switched magnetic field gradients of the third and fourth imaging sequence have opposed polarity;
deriving the spatial distribution of electrical properties of the object from the first, second, third, and forth MR signals and wherein the object is rotated by 90° about an axis perpendicular to a main magnetic field axis of the MR device after acquisition of the first and second MR signals and before acquisition of the third and forth MR signals

6. (canceled)

7. Method of claim 5, wherein the spatial directions of the switched magnetic field gradients of the first and second imaging sequences are different from the spatial directions of the switched magnetic field gradients of the third and forth imaging sequences.

8. Method of claim 5, wherein three-dimensional MR phase images are reconstructed from the first, second, third, and forth MR signals respectively.

9. MR device for carrying out the method as claimed in claim 1, which MR device includes at least one main magnet coil for generating a uniform, steady magnetic field within an examination volume, a number of gradient coils for generating switched magnetic field gradients in different spatial directions within the examination volume, at least one RF coil for generating RF pulses within the examination volume and/or for receiving MR signals from an object positioned in the examination volume, a control unit for controlling the temporal succession of RF pulses and switched magnetic field gradients, and a reconstruction unit, wherein the MR device is arranged to perform the following steps:
subjecting the object to two or more imaging sequences for acquiring MR signals, wherein the imaging sequences each comprise at least one RF pulse and at least one switched magnetic field gradient for spatial encoding in the MR imaging;
reconstructing two or more MR phase images from MR signals acquired by means of imaging sequences comprising switched magnetic field gradients for spatial encoding in the MR imaging of opposed polarity;
deriving a spatial distribution of electrical properties of the object (10) from the MR phase images.

10. Computer program to be run on a MR device, which computer program comprises instructions for:
generating two or more imaging sequences for acquiring MR signals, wherein the imaging sequences each comprise at least one RF pulse and at least one switched magnetic field gradient for spatial encoding in the MR imaging;
reconstructing two or more MR phase images from MR signals acquired by means of imaging sequences comprising switched magnetic field gradients of opposed polarity for spatial encoding in the MR imaging;
deriving a spatial distribution of electrical properties of an object (10) from the MR phase images.
